(19) United States
(12) Patent Application Publication
(10) Pub. No.: US 2025/0278306 A1
(43) Pub. Date: Sep. 4, 2025

(54) ALLOCATION OF REPAIR RESOURCES IN A MEMORY DEVICE

(71) Applicant: Micron Technology, Inc., Boise, ID (US)

(72) Inventors: Nicola CORNA, Gorle (IT); Nicola DEL GATTO, Cassina De' Pecchi (IT); Angelo Alberto ROVELLI, Agrate Brianza (IT)

(21) Appl. No.: 19/042,745

(22) Filed: Jan. 31, 2025

Related U.S. Application Data
(60) Provisional application No. 63/559,805, filed on Feb. 29, 2024.

(51) Int. Cl. G06F 9/50; G11C 29/44

(52) U.S. Cl. CPC G06F 9/505; G11C 29/4401

(57) ABSTRACT

In some implementations, a central processing unit (CPU) associated with a controller of a memory device may determine that a portion of a memory associated with a logical address is to be repaired. The CPU and/or a resources tracker component associated with the controller a may determine an allocated portion of spare resources to be used to repair the portion of the memory. The CPU and/or a resources tracker component may transmit, to a spare resources engine associated with the controller, a repair request that indicates the logical address and the allocated portion of spare resources. The spare resources engine may write information associated with the repair request to the allocated portion of spare resources.

### CROSS-REFERENCE TO RELATED APPLICATION

This patent application claims priority to U.S. Provisional Patent Application No. 63/559,805, filed on Feb. 29, 2024, entitled “ALLOCATION OF REPAIR RESOURCES IN A MEMORY DEVICE,” and assigned to the assignee hereof. The disclosure of the prior application is considered part of and is incorporated by reference into this patent application.

### TECHNICAL FIELD

The present disclosure generally relates to memory devices, memory device operations, and, for example, to allocation of repair resources in a memory device.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. In some examples, a memory device may be associated with a compute express link (CXL). For example, the memory device may be a CXL-compliant memory device and/or may include a CXL interface.

### BRIEF DESCRIPTION OF THE DRAWINGS

FIG. 1 is a diagram illustrating an example system capable of allocating repair resources in a memory device.

FIGS. 2A-2B are diagrams related to an example associated with allocating repair resources by a spare resources engine of a memory device.

FIGS. 3A-3B are diagrams of an example of allocating repair resources in a memory device.

FIG. 4 is a flowchart of an example method associated with allocating repair resources in a memory device.

FIG. 5 is a diagram illustrating example systems in which the memory device described herein may be used.

### DETAILED DESCRIPTION

In some examples, portions of a memory may degrade during a lifetime of the memory and thus may not function properly. For example, certain portions of a computer express link (CXL)-compliant memory device (sometimes referred to herein simply as a “CXL memory”) may degrade over time, resulting in data loss and/or otherwise unreliable memory if the CXL memory device is not repaired. In some cases, a dedicated hardware component in a memory controller, which is sometimes referred to as a spare resources engine, may be used to allocate repair resources (sometimes alternatively referred to herein as spare resources) for use in repairing a degraded or otherwise unreliable portion of a memory. Such hardware components (e.g., spare resource engines) may be inflexible because the hardware blocks may not have a capability of being reprogrammed and/or otherwise altered after being implemented within a memory controller (e.g., within an application-specific integrated circuit (ASIC) associated with a memory controller), and/or may result in relatively slow and/or resource-intensive memory operations. More particularly, allocating repair resources using a spare resources engine and/or a similar hardware component may be associated with high latency due to the various requests and replies that may need to be exchanged among memory device components (e.g., between a central processing unit (CPU) and the spare resources engine), the various read operations that may need to be performed by the spare resource engine, and/or the various computations that may need to be performed by spare resources engine. Moreover, allocating spare resources using a spare resources engine and/or a similar hardware component may be associated with high central-controller overhead, because complex hardware components (e.g., a complex spare resources engines) may need to be employed to handle the various repair operations. Additionally, allocating spare resources using a spare resources engine and/or a similar hardware component may be associated with high power, computing, and storage resource consumption associated with performing the various repair resource allocation operations.

Some implementations described herein enable allocation of repair resources using firmware running on a central controller CPU and/or by a resource tracker component associated with the CPU, thereby reducing complexity, latency, overhead, and/or resource consumption associated with allocation of repair resources. In some implementations, a CPU of a central controller may determine that a portion of a memory associated with a logical address is to be repaired. The CPU and/or a resources tracker component associated with the CPU may determine an allocated portion of spare resources to be used to repair the portion of the memory, and/or may transmit, to a spare resources engine, a repair request that indicates the logical address and the allocated portion of spare resources. In this way, the spare resources engine need to not determine available spare resources to be used for the repair request. Instead, the spare resources engine may simply write information associated with the repair request to the allocated portion of spare resources as indicated by the repair request received from the CPU and/or the resources tracker component. Management of allocation of repair resources in firmware running on a CPU and/or by a resource tracker component associated with the CPU may result in reduced latency as compared to allocating spare resources using a spare resources engine and/or a similar hardware component, reduced central-controller overhead as compared to allocating spare resources using a spare resources engine and/or a similar hardware component, and/or reduced power, computing, and storage resource consumption as compared to allocating spare resources using a spare resources engine and/or a similar hardware component.

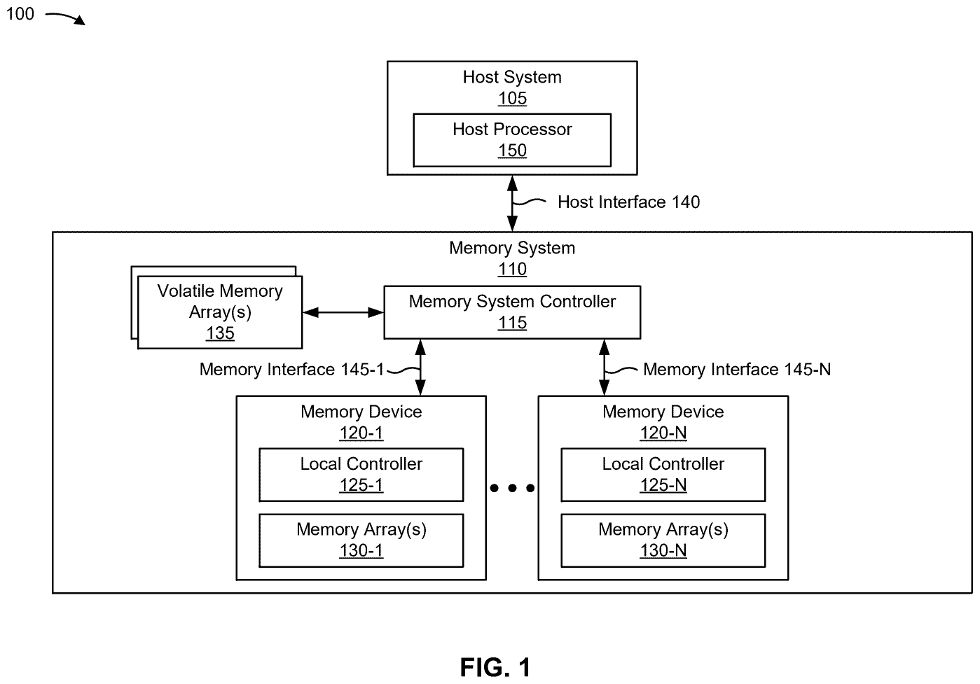

FIG. 1 is a diagram illustrating an example system 100 capable of allocating repair resources in a memory device. The system 100 may include one or more devices, apparatuses, and/or components for performing operations described herein. For example, the system 100 may include a host system 105 and a memory system 110. The memory system 110 may include a memory system controller 115 and one or more memory devices 120, shown as memory devices 120-1 through 120-N (where N≥1). A memory device may include a local controller 125 and one or more memory arrays 130. The host system 105 may communicate with the memory system 110 (e.g., the memory system controller 115 of the memory system 110) via a host interface 140. The memory system controller 115 and the memory devices 120 may communicate via respective memory interfaces 145, shown as memory interfaces 145-1 through 145-N (where N≥1).

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host system 105 may include a host processor 150. The host processor 150 may include one or more processors configured to execute instructions and store data in the memory system 110. For example, the host processor 150 may include a central processing unit (CPU), a graphics processing unit (GPU), a field-programmable gate array (FPGA), an application-specific integrated circuit (ASIC), and/or another type of processing component.

The memory system 110 may be any electronic device or apparatus configured to store data in memory. For example, the memory system 110 may be a hard drive, a solid-state drive (SSD), a flash memory system (e.g., a NAND flash memory system or a NOR flash memory system), a universal serial bus (USB) drive, a memory card (e.g., a secure digital (SD) card), a secondary storage device, a non-volatile memory express (NVMe) device, an embedded multimedia card (eMMC) device, a dual in-line memory module (DIMM), and/or a random-access memory (RAM) device, such as a dynamic RAM (DRAM) device or a static RAM (SRAM) device.

The memory system controller 115 may be any device configured to control operations of the memory system 110 and/or operations of the memory devices 120. For example, the memory system controller 115 may include control logic, a memory controller, a system controller, an ASIC, an FPGA, a processor, a microcontroller, and/or one or more processing components. In some implementations, the memory system controller 115 may communicate with the host system 105 and may instruct one or more memory devices 120 regarding memory operations to be performed by those one or more memory devices 120 based on one or more instructions from the host system 105. For example, the memory system controller 115 may provide instructions to a local controller 125 regarding memory operations to be performed by the local controller 125 in connection with a corresponding memory device 120.

A memory device 120 may include a local controller 125 and one or more memory arrays 130. In some implementations, a memory device 120 includes a single memory array 130. In some implementations, each memory device 120 of the memory system 110 may be implemented in a separate semiconductor package or on a separate die that includes a respective local controller 125 and a respective memory array 130 of that memory device 120. The memory system 110 may include multiple memory devices 120.

A local controller 125 may be any device configured to control memory operations of a memory device 120 within which the local controller 125 is included (e.g., and not to control memory operations of other memory devices 120). For example, the local controller 125 may include control logic, a memory controller, a system controller, an ASIC, an FPGA, a processor, a microcontroller, and/or one or more processing components. In some implementations, the local controller 125 may communicate with the memory system controller 115 and may control operations performed on a memory array 130 coupled with the local controller 125 based on one or more instructions from the memory system controller 115. As an example, the memory system controller 115 may be an SSD controller, and the local controller 125 may be a NAND controller.

A memory array 130 may include an array of memory cells configured to store data. For example, a memory array 130 may include a non-volatile memory array (e.g., a NAND memory array or a NOR memory array) or a volatile memory array (e.g., an SRAM array or a DRAM array). In some implementations, the memory system 110 may include one or more volatile memory arrays 135. A volatile memory array 135 may include an SRAM array and/or a DRAM array, among other examples. The one or more volatile memory arrays 135 may be included in the memory system controller 115, in one or more memory devices 120, and/or in both the memory system controller 115 and one or more memory devices 120. In some implementations, the memory system 110 may include both non-volatile memory capable of maintaining stored data after the memory system 110 is powered off and volatile memory (e.g., a volatile memory array 135) that requires power to maintain stored data and that loses stored data after the memory system 110 is powered off. For example, a volatile memory array 135 may cache data read from or to be written to non-volatile memory, and/or may cache instructions to be executed by a controller of the memory system 110.

The host interface 140 enables communication between the host system 105 (e.g., the host processor 150) and the memory system 110 (e.g., the memory system controller 115). The host interface 140 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, an eMMC interface, a double data rate (DDR) interface, and/or a DIMM interface.

The memory interface 145 enables communication between the memory system 110 and the memory device 120. The memory interface 145 may include a non-volatile memory interface (e.g., for communicating with non-volatile memory), such as a NAND interface or a NOR interface. Additionally, or alternatively, the memory interface 145 may include a volatile memory interface (e.g., for communicating with volatile memory), such as a DDR interface.

In some examples, the memory system 110 may be a CXL-compliant memory system (sometimes referred to herein simply as a CXL memory system) and/or one or more of the memory devices 120 may be CXL-compliant memory devices (e.g., CXL memory devices). CXL is a high-speed CPU-to-device and CPU-to-memory interconnect designed to accelerate next-generation performance. CXL technology maintains memory coherency between the CPU memory space and memory on attached devices, which allows resource sharing for higher performance, reduced software stack complexity, and lower overall system cost. CXL is designed to be an industry open standard interface for high-speed communications. CXL technology is built on the PCIe infrastructure, leveraging PCIe physical and electrical interfaces to provide an advanced protocol in areas such as input/output (I/O) protocol, memory protocol, and coherency interface.

In some examples, the memory system 110 may include a PCIe/CXL interface (e.g., the host interface 140 may be associated with a PCIe/CXL interface), which may be a physical interface configured to connect the CXL memory system and/or the CXL memory device to CXL compliant host devices. In such examples, the PCIe/CXL interface may comply with CXL standard specifications for physical connectivity, ensuring broad compatibility and case of integration into existing systems using the CXL protocol. Additionally, or alternatively, a CXL memory system and/or a CXL memory device may be designed to efficiently interface with computing systems (e.g., the host system 105) by leveraging the CXL protocol. For example, a CXL memory system and/or a CXL memory device may be configured to utilize high-speed, low-latency interconnect capabilities of CXL, such as for a purpose of making the CXL memory system and/or the CXL memory device suitable for high-performance computing, data center applications, artificial intelligence (AI) applications, and/or similar applications.

A CXL memory system and/or a CXL memory device may include a CXL memory controller (e.g., memory system controller 115 and/or local controller 125), which may be configured to manage data flow between memory arrays (e.g., volatile memory arrays 135 and/or memory arrays 130) and a CXL interface (e.g., a PCIe/CXL interface, such as host interface 140). In some examples, the CXL memory controller may be configured to handle one or more CXL protocol layers, such as an I/O layer (e.g., a layer associated with a CXL.io protocol, which may be used for purposes such as device discovery, configuration, initialization, I/O virtualization, direct memory access (DMA) using non-coherent load-store semantics, and/or similar purposes); a cache coherency layer (e.g., a layer associated with a CXL.cache protocol, which may be used for purposes such as caching host memory using a modified, exclusive, shared, invalid (MESI) coherence protocol, or similar purposes); or a memory protocol layer (e.g., a layer associated with a CXL.memory (sometimes referred to as CXL.mem) protocol, which may enable a CXL memory device to expose host-managed device memory (HDM) to permit a host device to manage and access memory similar to a native DDR connected to the host); among other examples.

A CXL memory system and/or a CXL memory device may further include and/or be associated with one or more high-bandwidth memory modules (HBMMs) or similar memory arrays (e.g., volatile memory arrays 135 and/or memory arrays 130). For example, a CXL memory system and/or a CXL memory device may include multiple layers of DRAM (e.g., stacked and/or interconnected through advanced through-silicon via (TSV) technology) in order to maximize storage density and/or enhance data transfer speeds between memory layers. Additionally, or alternatively, a CXL memory system and/or a CXL memory device may include a power management unit, which may be configured to regulate power consumption associated with the CXL memory system and/or the CXL memory device and/or which may be configured to improve energy efficiency for the CXL memory system and/or the CXL memory device. Additionally, or alternatively, a CXL memory system and/or a CXL memory device may include additional components, such as one or more error correction code (ECC) engines, such as for a purpose of detecting and/or correcting data errors to ensure data integrity and/or improve the overall reliability of the CXL memory system and/or the CXL memory device.

Although the example memory system 110 described above includes a memory system controller 115, in some implementations, the memory system 110 does not include a memory system controller 115. For example, an external controller (e.g., included in the host system 105) and/or one or more local controllers 125 included in one or more corresponding memory devices 120 may perform the operations described herein as being performed by the memory system controller 115. Furthermore, as used herein, a “controller” may refer to the memory system controller 115, a local controller 125, or an external controller. In some implementations, a set of operations described herein as being performed by a controller may be performed by a single controller. For example, the entire set of operations may be performed by a single memory system controller 115, a single local controller 125, or a single external controller. Alternatively, a set of operations described herein as being performed by a controller may be performed by more than one controller. For example, a first subset of the operations may be performed by the memory system controller 115 and a second subset of the operations may be performed by a local controller 125. Furthermore, the term “memory apparatus” may refer to the memory system 110 or a memory device 120, depending on the context.

A controller (e.g., the memory system controller 115, a local controller 125, or an external controller) may control operations performed on memory (e.g., a memory array 130), such as by executing one or more instructions. For example, the memory system 110 and/or a memory device 120 may store one or more instructions in memory as firmware, and the controller may execute those one or more instructions. Additionally, or alternatively, the controller may receive one or more instructions from the host system 105 and/or from the memory system controller 115, and may execute those one or more instructions. In some implementations, a non-transitory computer-readable medium (e.g., volatile memory and/or non-volatile memory) may store a set of instructions (e.g., one or more instructions or code) for execution by the controller. The controller may execute the set of instructions to perform one or more operations or methods described herein. In some implementations, execution of the set of instructions, by the controller, causes the controller, the memory system 110, and/or a memory device 120 to perform one or more operations or methods described herein. In some implementations, hardwired circuitry is used instead of or in combination with the one or more instructions to perform one or more operations or methods described herein. Additionally, or alternatively, the controller may be configured to perform one or more operations or methods described herein. An instruction is sometimes called a “command.”

For example, the controller (e.g., the memory system controller 115, a local controller 125, or an external controller) may transmit signals to and/or receive signals from memory (e.g., one or more memory arrays 130) based on the one or more instructions, such as to transfer data to (e.g., write or program), to transfer data from (e.g., read), to erase, and/or to refresh all or a portion of the memory (e.g., one or more memory cells, pages, sub-blocks, blocks, or planes of the memory). Additionally, or alternatively, the controller may be configured to control access to the memory and/or to provide a translation layer between the host system 105 and the memory (e.g., for mapping logical addresses to physical addresses of a memory array 130). In some implementations, the controller may translate a host interface command (e.g., a command received from the host system 105) into a memory interface command (e.g., a command for performing an operation on a memory array 130).

In some implementations, one or more systems, devices, apparatuses, components, and/or controllers of FIG. 1 may be configured to determine, by a central processing unit (CPU) associated with a controller, that a portion of a memory associated with a logical address is to be repaired; determine, by at least one of the CPU or a resources tracker component associated with the controller, an allocated portion of spare resources to be used to repair the portion of the memory; transmit, by the at least one of the CPU or the resources tracker component to a spare resources engine associated with the controller, a repair request, wherein the repair request indicates the logical address and the allocated portion of spare resources; and write, by the spare resources component to the allocated portion of spare resources, information associated with the repair request.

The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more operations described as being performed by another set of components shown in FIG. 1.

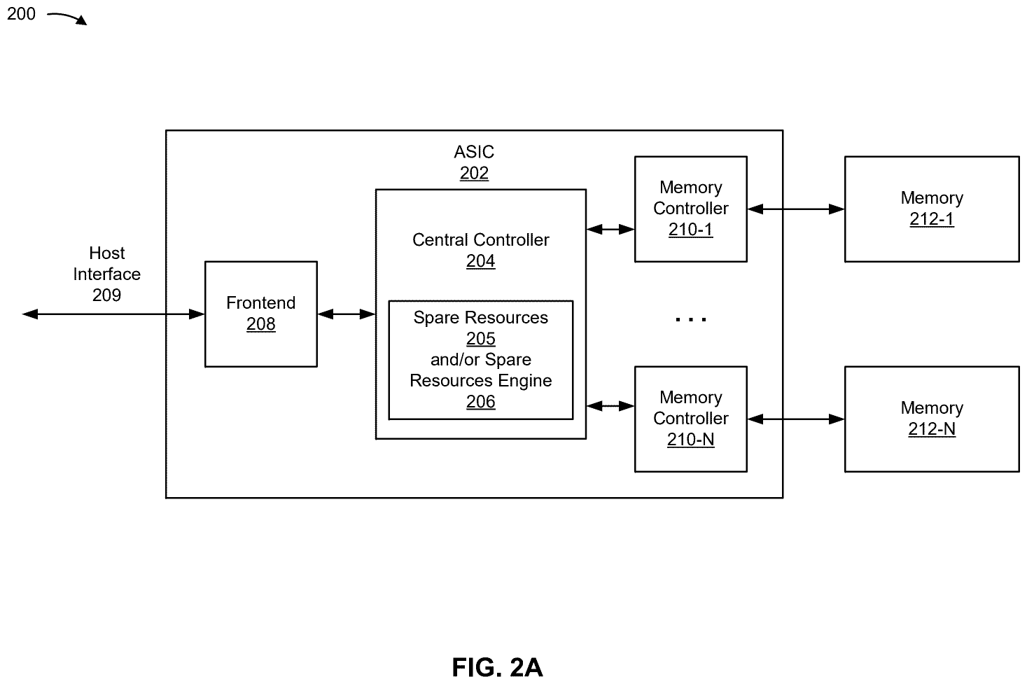

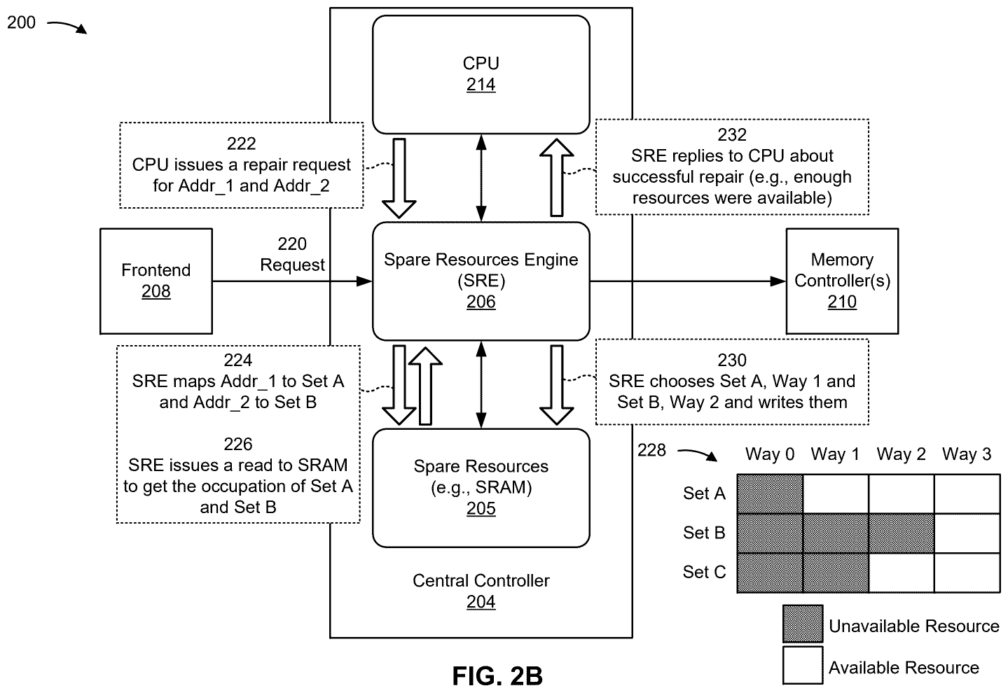

FIGS. 2A-2B are diagrams related to an example 200 associated with allocating repair resources by a spare resources engine of a memory device. The operations described in connection with FIGS. 2A-2B may be performed by the memory system 110 and/or one or more components of the memory system 110, such as the memory system controller 115, one or more memory devices 120, and/or one or more local controllers 125.

In some examples, certain portions of a memory may degrade during a lifetime of the memory and thus may not function properly. For example, certain portions of a CXL memory device may degrade over time, resulting in data loss and/or otherwise unreliable memory if the CXL memory device is not repaired. In some cases, a dedicated hardware component in a memory controller, which is sometimes referred to herein as a spare resources engine, may be used to allocate spare resources, such as for use in repairing a degraded or otherwise unreliable portion of a memory. Such hardware components (e.g., spare resource engines) may be inflexible because the hardware blocks cannot be reprogrammed and/or otherwise altered after being implemented within a memory controller (e.g., within an ASIC), and/or may result in relatively slow and/or resource-intensive memory operations.

More particularly, FIG. 2A shows one example of hardware components that may be used to repair a memory device (e.g., a CXL memory device) and/or allocate repair resources for a purpose of repairing a memory device. As shown in FIG. 2A, certain hardware components may form part of, or otherwise be associated with, an ASIC 202 that is associated with one or more controllers in a memory device (e.g., a CXL memory device). The ASIC 202 may be associated with a central controller 204, which may correspond to the memory system controller 115 described above in connection with FIG. 1. The central controller 204 may include spare resources 205 and/or a spare resources engine 206 used to allocate the spare resources 205 during repair of a degrading or failing memory, which is described in more detail below. The spare resources 205 may be SRAM or a similar type of memory local to the central controller 204, and/or the spare resources engine 206 may be a hardware block of the central controller 204 that is used to allocate spare resources 205 to be used to repair a portion of a memory (e.g., to be used to repair DRAM or a similar type of memory). In some examples, the spare resources engine 206 may be a component that manages spare memory units (e.g., the spare resources 205) that can be used to replace faulty memory units (e.g., faulty DRAM units). For example, when a memory controller (e.g., memory system controller 115, local controller 125, central controller 204, and/or memory controller 210) detects an error and/or a failing memory segment, the spare resources engine 206 may be capable of reallocating memory accesses to the spare resources 205, which is described in more detail below in connection with FIG. 2B.

The ASIC 202 may further include one or more memory controllers 210 (shown in FIG. 2A as a first memory controller 210-1 through an N-th memory controller 210-N), which may correspond to one or more local controllers 125 described above in connection with FIG. 1, each of which may be in communication with a corresponding memory (shown in FIG. 2A as a first memory 212-1 through an N-th memory 212-N), which may correspond to one or more of the memory arrays 130 described above in connection with FIG. 1. Additionally, or alternatively, the ASIC 202 may include a frontend component 208. The frontend component 208 may include one or more components associated with logic located between a host interface 209 (e.g., the host interface 140) and the central controller 204. The frontend component 208 may include one or more components that are configured to perform one or more functions associated with communicating with a host device (e.g., host system 105) via the host interface 209 (e.g., via a PCIe/CXL interface, among other examples), such as by performing protocol conversion functionality (e.g., conversion of a data stream into CXL packets), performing serializer/deserializer (SerDes) functionality (e.g., converting parallel data streams to serial data streams during transmission and/or converting serial data streams to parallel data streams upon reception), performing arbitrator and multiplexer (ARBMUX) functionality (e.g., dynamically multiplexing data coming from multiple protocols and/or routing the multiplexed data to the physical layer), performing analog front end (AFE) functionality (e.g., managing analog aspects of high-speed serial data transmission, such as by conditioning signals, equalizing data, recovering clock information, adapting to channel characteristics, among other examples), and/or performing similar functionality.

FIG. 2B illustrates one example of how the central controller 204, and more particularly certain components of the central controller 204, may perform a repair operation associated with a memory and/or process a request 220 that is received from a host device (e.g., a read and/or write request) and is forwarded to the central controller 204 via the frontend component 208 and that is associated with a repaired portion of memory. As shown in FIG. 2B, the spare resources engine 206 may be placed between the frontend component 208 and the one or more memory controllers 210, such that requests (e.g., request 220 and/or similar requests) received from the frontend component 208 may be forwarded to an appropriate memory controller 210 in instances in which a memory location associated with the request 220 has not failed and/or has not been repaired, and/or such that requests received from the frontend component 208 may be forwarded to the spare resources 205 (e.g., SRAM) in instances in which a memory location associated with the request 220 has failed and/or has been repaired using the spare resources 205. Moreover, the spare resources engine 206 may be in communication with a CPU 214 of the central controller 204, which may be a portion of the central controller 204 responsible for managing the various components and/or operations of the memory device. For example, the CPU 214 may perform interconnect management functionality (e.g., manage CXL interconnects), memory coherency functionality (e.g., ensuring data accessible by multiple devices is consistent, thereby avoiding data duplication and/or synchronization issues), protocol handling functionality (e.g., managing memory read/writes, I/O operations, and/or other transactions over a CXL interconnect), resource allocation and management functionality (e.g., allocating and managing memory resources across different devices, such as by managing access rights, prioritizing requests, and/or optimizing the use of shared resources, among other operations), and/or performance optimization functionality (e.g., optimize the performance of memory-intensive applications in data centers, cloud computing, artificial intelligence/machine learning (AI/ML) workloads, and/or similar environments). In this regard, the CPU 214 may, in some examples, determine whether a portion of a memory has failed and thus needs repair (e.g., whether a portion of a memory should be replaced using a portion of the spare resources 205) and/or the CPU 214 may instruct the spare resources engine 206 to initiate a repair.

More particularly, as indicated by reference number 222, in some examples the CPU 214 may determine that one or more portions of a memory have failed, and thus may issue a repair request to the spare resources engine 206 that instructs the spare resources engine 206 to perform a repair for the one or more portions of memory (e.g., that instructs the spare resources engine 206 to allocate spare resources as a replacement for the one or portions of memory that have failed). For example, in the example depicted in FIG. 2B, the CPU 214 may determine that a first portion of a memory associated with a first logical address (shown in FIG. 2B as “Addr_1”) and/or that a second portion of a memory associated with a second logical address (shown in FIG. 2B as “Addr_2”) have failed and/or are in need of repair. Accordingly, the CPU 214 may issue a repair request to the spare resources engine 206 that identifies the first portion of the memory (e.g., the portion of the memory associated with Addr_1) and/or the second portion of the memory (e.g., the portion of the memory associated with Addr_2) as portions of the memory requiring repair.

As indicated by reference numbers 224 and 226, the spare resources engine 206 may map the logical addresses associated with the portions of the memory requiring repair (e.g., Addr_1 and/or Addr_2) to a set of spare resources, and/or the spare resources engine 206 may determine a portion of the set of spare resources (e.g., may determine a way identifier) to be used as a replacement for the failing portions of memory. More particularly, as indicated by reference number 228, the spare resources 205 (e.g., SRAM) may include multiple sets of spare resources (shown in FIG. 2B as three sets of spare resources, indexed as Set A through Set C), with each set of spare resources being associated with multiple ways (shown in FIG. 2B as four ways for each set of spare resources, indexed as Way 0 through Way 3). Accordingly, as indicated by reference number 224, the spare resources engine 206 may associate a portion of memory needing repair with a corresponding set of spare resources, such as by using a set-associative structure. A set-associative structure refers to a structure used to organize and access data in cache memory (e.g., the spare resources 205) in which the cache memory is divided into multiple sets (e.g., Set A through Set C), with each set being associated with multiple ways (e.g., Way 0 through Way 3). In such examples, a given portion of memory may be replaced by any available way in a set that is associated with the portion of memory.

In that regard, based on a set-associative structure or a similar structure, the spare resources engine 206 may map each logical address (e.g., Addr_1 and Addr_2) to a corresponding set, such as by mapping Addr_1 to Set A and/or by mapping Addr_2 to Set B. Moreover, the spare resources engine 206 may identify which ways in each set that are available to be used as replacement resources for the failing portions of memory (e.g., the portions associated with Addr_1 and Addr_2). More particularly, as indicated by reference number 228, each set may be associated with some ways that are unavailable (e.g., ways that have been previously written to, shown in FIG. 2B using stippling) and other ways that are available (e.g., ways that have not been previously written to and thus that are still available as a replacement for a failing portion of the memory, shown in FIG. 2B using an absence of stippling). Accordingly, the spare resources engine 206 may determine a status of the various ways for a given set (e.g., one of unavailable or available for each way of a given set, sometimes referred to herein as an occupation of the given set), such as by reading the spare resources 205 (e.g., the SRAM). More particularly, returning to the example in which the spare resources engine 206 maps Addr_1 to Set A and Addr_2 to Set B, the spare resources engine 206 may issue a read command to the spare resources 205 (e.g., the SRAM) in order determine an occupation of Set A and/or an occupation of Set B, as indicated by reference number 226. In such cases, the read command may identify that Way 0 of Set A is unavailable (e.g., occupied), but that Way 1, Way 2, and/or Way 3 are available to serve as replacement for the failing portion of memory. Similarly, the read command may identify that Way 0, Way 1, and Way 2 of Set B are unavailable (e.g., occupied), but that Way 3 is available to serve as replacement for the failing portion of memory.

As indicated by reference number 230, the spare resources engine 206 may determine an allocated portion of the spare resources 205 that are to be used as replacement resources for the failing portions of the memory (e.g., the portions of the memory associated with Addr_1 and Addr_2). More particularly, as described above in connection with reference number 226, the spare resources engine 206 may identify (e.g., using a read command issued to the spare resources 205), that Way 1 of Set A is the first available resource for Set A, and/or that Way 3 of Set B is the first available resource for Set B. Accordingly, the spare resources engine 206 may determine that Set A, Way I should be used as a replacement resource for the portion of memory associated with Addr_1, and/or that Set B, Way 3 should be used as a replacement resource for the portion of memory associated with Addr_2. Moreover, the spare resources engine 206 may write data to the allocated spare resources, such as by writing data originally stored at the first memory location (e.g., the physical memory location associated with Addr_1) to Set A, Way 1 and/or by writing data originally stored at the second memory location (e.g., the physical memory location associated with Addr_2) to Set B, Way 3.

In this way, if the central controller 204 receives a request associated with a portion of memory that has been repaired (e.g., a portion of memory associated with Addr_1 and/or Addr_2 in the above example), the central controller 204 (more particularly, the spare resources engine 206 of the central controller 204) may direct the request to the spare resources 205. For example, if the central controller 204 receives a request (e.g., request 220) from a host device (e.g., via the frontend component 208) that is associated with Addr_1, the spare resources engine 206 may direct the request to the spare resources 205, and, more particularly, to Set A, Way 1 of the spare resources 205. Similarly, if the central controller 204 receives a request (e.g., request 220) from a host device (e.g., via the frontend component 208) that is associated with Addr_2, the spare resources engine 206 may direct the request to the spare resources 205, and, more particularly, to Set B, Way 3 of the spare resources 205.

Additionally, or alternatively, as indicated by reference number 232, the spare resources engine 206 may transmit an indication to the CPU 214 that the memory was successfully repaired. For example, in cases in which each set of spare resources that are associated with the portions of memory to be repaired has available resources for performing a repair, the spare resources engine 206 may transmit an indication to the CPU 214 indicating that a successful repair was performed (e.g., indicating that sufficient resources were available at the spare resources 205 to make the requested repair). Returning to the above-described example, because in this example there were enough resources to make the repair (e.g., because Set A included an available way to replace the portion of the memory associated with Addr_1 and because Set B included an available way to replace the portion of the memory associated with Addr_2), the spare resources engine 206 may reply to the CPU 214 that the requested repair was successful.

In that regard, allocating spare resources in the manner described above may be associated with high latency due to the various requests and replies that may need to be exchanged among central controller components (e.g., the requests and replies described above in connection with reference numbers 222 and 232), the various read operations that may need to be performing by central controller components (e.g., the read operations described above in connection with reference number 226), and/or the various determinations that need to be performed by the various central controller components (e.g., the determinations described above in connection with reference numbers 224 and 230). Moreover, allocating spare resources in the manner described above may be associated with high central-controller overhead, because complex hardware components (e.g., complex spare resources engines) may need to be employed to handle the various operations described above. Additionally, allocating spare resources in the manner described above may be associated with high power, computing, and storage resource consumption associated with performing the various operations described above.

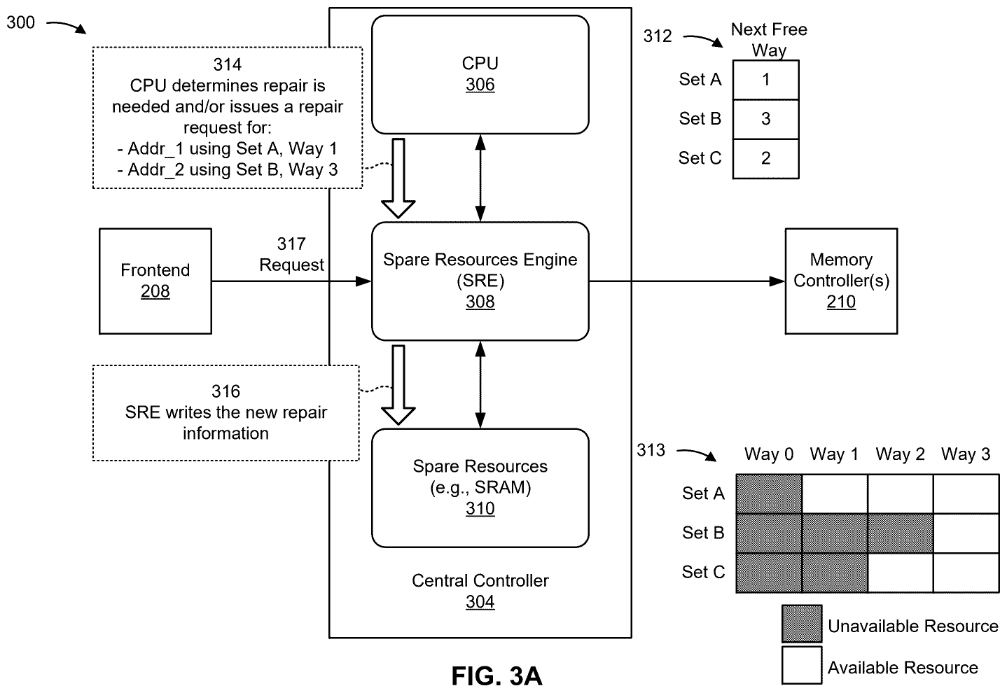

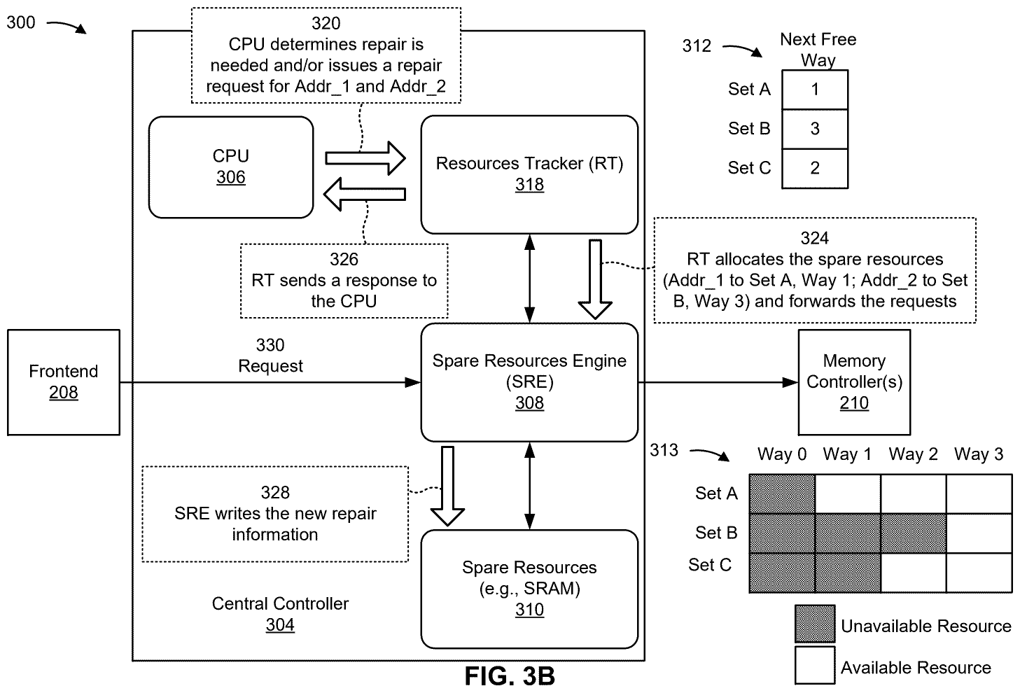

Some implementations described herein enable management of allocation of repair resources using firmware running on a central controller CPU (e.g., CPU 214) and/or by a resource tracker component associated with the central controller CPU. As a result, allocating spare resources according to some implementations described herein may result in reduced latency as compared to the operations described above in connection with FIG. 2B, reduced central-controller overhead as compared to the operations described above in connection with FIG. 2B, and/or reduced power, computing, and storage resource consumption as compared to the operations described above in connection with FIG. 2B. This may be more readily understood with reference to FIGS. 3A-3B.

As indicated above, FIGS. 2A-2B are provided as an example. Other examples may differ from what is described with regard to FIGS. 2A-2B.

FIGS. 3A-3B are diagrams of an example 300 of allocating repair resources in a memory device. The operations described in connection with FIGS. 3A-3B may be performed by the memory system 110 and/or one or more components of the memory system 110, such as the memory system controller 115, one or more memory devices 120, and/or one or more local controllers 125, and/or by an ASIC (e.g., similar to ASIC 202) and/or one or more components of an ASIC, such as by a central controller 304 (which may be similar to the central controller 204), a CPU 306 associated with the central controller 304 (which may be similar to the CPU 214), a spare resources engine 308 of the central controller 304 (which may be similar to the spare resources engine 206, but which may be associated with a reduced hardware complexity as compared to the spare resources engine 206, which is described in more detail below), spare resources 310 of the central controller 304 (which may be similar to the spare resources 205 and/or which may be SRAM or a similar type of a memory), the frontend component 208, one or more memory controllers 210, and/or a resource tracker component 318 (which is described in more detail below in connection with FIG. 3B).

Additionally, or alternatively, in some implementations one or more components shown and described in connection with FIGS. 3A and 3B may form part of an ASIC (e.g., similar to the ASIC 202 shown in FIG. 2A). For example, in some implementations (e.g., CXL-based implementations and/or implementations in which one or more components shown in FIGS. 3A and 3B form part of a CXL memory device), the CPU 306, the resources tracker component 318, the spare resources engine 308, and/or the spare resources 310 may be part of an ASIC associated with the central controller 304.

In the implementation shown in FIG. 3A, the CPU 306 may keep track of available repair resources (e.g., the CPU 306 may keep track of the next available way at each set of spare resources) and thus may indicate an allocated portion of spare resources (e.g., a set and/or way) that is to be used for a repair request. Put another, the CPU 306 may keep track of the available resources in the spare resources 310 (e.g., SRAM located at the central controller 304) and thus the CPU 306 may directly manage the allocation of the spare resources and/or send, to the spare resources engine 308, an indication of which resource to use for a repair together with the repair request. In this way, the allocation of the repair resources may be managed in firmware running on the CPU 306, lowering the cost and complexity of the central controller 304, while also enabling a reduced risk and more flexible solution than hardware-based implementations (e.g., implementations in which a spare resources engine allocates spare resources in response to receiving a repair request, as described above in connection with FIGS. 2A-2B). Additionally, or alternatively, information regarding available resources (e.g., information regarding the next available way for each set of spare resources) may be tracked using a lower memory footprint than hardware-based implementations.

More particularly, as indicated by reference number 312, the CPU 306 may store in local memory information regarding a next available resource (e.g., the next available way) for each set of spare resources. For example, in implementations in which the spare resources 310 are organized into sets of spare resources (e.g., Set A through Set C), with each set of spare resources being organized into multiple ways (e.g., Way 0 through Way 3), as described above in connection with reference number 228 and as shown in FIG. 3A in connection with reference number 313, the CPU 306 may keep track of the next available way for each set. For example, in the implementation shown in FIG. 3A, the CPU 306 may keep track of which resources (e.g., ways) have been allocated for repair jobs in the past such that the CPU 306 may identify that the next available way for Set A is Way 1, the next available way for Set B is Way 3, and/or the next available way for Set C is Way 2.

As indicated by reference number 314, the CPU 306 may determine that a portion of a memory associated with a logical address is to be repaired. For example, in some implementations the CPU 306 may determine that a first portion of memory associated with a first logical address (e.g., Addr_1) and/or that a second portion of memory associated with a second logical address (e.g., Addr_2) is to be repaired. Because the CPU 306 may be aware of the next available resource for each set (as described above in connection with reference number 312), rather than issuing a generic repair request to the spare resources engine 308 (e.g., as described above in connection with reference number 222), the CPU 306 may determine an allocated portion of spare resources to be used to repair the portion of the memory and thus issue a repair request that indicates the logical address associated with the portion of the memory to be repaired as well as the allocated portion of spare resources to be used to repair the portion of the memory. More particularly, as further indicated by reference number 314, the CPU 306 may transmit a repair request to the spare resources engine 308 that indicates that the spare resources engine 308 is to repair the portion of the memory associated with Addr_1 using Set A, Way 1 and/or that that the spare resources engine 308 is to repair the portion of the memory associated with Addr_2 using Set B, Way 3.

In this regard, a complexity of the spare resources engine 308 may be decreased as compared to examples in which a spare resources engine is required to map a logical address to a set of spare resources using a set-associative structure or a similar method, issue a read operation to the spare resources (e.g., SRAM) to get an occupation of one or more sets to be used, and/or determine an available way for each set based on the read operation (e.g., as described above in connection with reference numbers 224, 226, 228, and 230 of FIG. 2B). Moreover, because in this implementation the spare resources engine 308 does not need to independently identify an occupation of the sets being used for the repair operation (e.g., Set A and Set B in the above-described example), the spare resources engine 308 may not require a read path to the spare resources 310 (e.g., the SRAM of the central controller 304), further reducing the complexity of the spare resources engine 308.

As indicated by reference number 316, the spare resources engine 308 may write, to the allocated portion of spare resources, information associated with the repair request (e.g., information originally stored in the portion of the memory being repaired and/or similar information). Again, the spare resources engine 308 may do so based on the information provided in the repair request received from the CPU 306 and thus without first requiring that the spare resources engine 308 map the logical addresses to sets of spare resources (e.g., without performing the operations described above in connection with reference number 224), without issuing a read operation to the spare resources in order to determine an occupation of the sets that are mapped to the logical addresses (e.g., without performing the operations described above in connection with reference number 226), and/or without choosing an available resource (e.g., way) of each set to be used for the repair operation (e.g., without performing some of the operations described above in connection with reference number 230). Additionally, or alternatively, there may be no need for the spare resources engine 308 to send a response to the CPU 306 indicating that a repair was successful and/or that enough repair resources were available for the repair operation (e.g., there may be no need for the spare resources engine to send the response described above in connection with reference number 232) because the CPU 306 may keep track of the available resources (as described above in connection with reference number 312) and thus may be already have information stored in local memory that the repair resources indicated in the repair request are available.

In this regard, if the central controller 304 receives a request (e.g., shown in FIG. 3A as request 317) from a host device (e.g., via the frontend component 208) that is associated with Addr_1, the spare resources engine 308 may direct the request to the spare resources 310, and, more particularly, to Set A, Way 1 of the spare resources 310. Similarly, if the central controller 304 receives a request (e.g., request 317) from a host device (e.g., via the frontend component 208) that is associated with Addr_2, the spare resources engine 308 may direct the request to the spare resources 310, and, more particularly, to Set B, Way 3 of the spare resources 310.

In some other implementations, a separate module (e.g., a component distinct from the CPU 306, such as the resources tracker component 318) may keep track of the available resources (may keep track of the next available way in each set of spare resources), such that the CPU 306 may send generic repair requests to the separate module (e.g., the resources tracker component 318), specifying the logical address to repair. In such implementations, a complexity of the spare resources engine 308 may be reduced in a similar manner as described above in connection with FIG. 3A, and/or the CPU 306 may not need to separately track available resources, thereby reducing the complexity of repair operations being performed by the CPU 306.

More particularly, as shown in FIG. 3B, the resources tracker component 318 may keep track of available repair resources, such as by storing information associated with the next available way for each set (e.g., as shown in connection with reference number 312) in local memory associated with the resources tracker component 318. Accordingly, when a repair operation is to be performed, the CPU 306 may transmit a generic repair request (e.g., a repair request that indicates a logical address to be repaired, but which does not indicate spare resources to which the logical address is mapped) to the resources tracker component 318, and the resources tracker component 318 may allocate repair resources for the operation and indicate the repair resources to the spare resources engine 308.

More particularly, as indicated by reference number 320, the CPU 306 may determine that a portion of a memory associated with a logical address is to be repaired. For example, the CPU 306 may determine that a first portion of memory associated with a first logical address (e.g., Addr_1) and/or that a second portion of memory associated with a second logical address (e.g., Addr_2) is to be repaired. Accordingly, the CPU 306 may transmit, to the resources tracker component 318, a generic repair request that indicates the one or more logical addresses (e.g., Addr_1 and Addr_2) to be repaired.

As indicated by reference number 324, the resources tracker component 318 may allocate sets and/or ways of the spare resources 310 that are to be used for the repair operation and/or the resources tracker component 318 may forward the repair request (including the logical addresses and associated allocated spare resources) to the spare resources engine 308. More particularly, the resources tracker component 318 may determine allocated portions of the spare resources 310 for the repair operation based on receiving the generic repair request from the CPU 306, such as by mapping Addr_1 to the next available way associated with Set A (e.g., Set A, Way 1) and/or by mapping Addr_2 to the next available way associated with Set B (e.g., Set B, Way 3). Additionally, or alternatively, the resources tracker component 318 may transmit, to the spare resources engine 308, the repair request that indicates the logical address associated with the portion of the memory to be repaired and the allocated portion of the spare resources 310 to be used to repair the portion of the memory. More particularly, as further indicated by reference number 324, the resources tracker component 318 may transmit a repair request to the spare resources engine 308 that indicates that the spare resources engine 308 is to repair the portion of the memory associated with Addr_1 using Set A, Way I and/or that that the spare resources engine 308 is to repair the portion of the memory associated with Addr_2 using Set B, Way 3.

In some implementations, the resources tracker component 318 may send a response to the CPU 306 indicating whether there were sufficient available resources (e.g., sufficient available ways) to complete to requested repair, which may be similar to the response described above in connection with reference number 232. More particularly, as indicated by reference number 326, the resources tracker component 318 may transmit an indication to the CPU 306 indicating that a successful repair was performed (e.g., indicating that sufficient resources were available at the spare resources 310 to make the requested repair). Returning to the above-described example, because in this example there were enough resources to make the repair (e.g., because Set A included an available way to replace the portion of the memory associated with Addr_1 and because Set B included an available way to replace the portion of the memory associated with Addr_2), the resources tracker component 318 may reply to the CPU 306 that the requested repair was successful.

As indicated by reference number 328, the spare resources engine 308 may write, to the allocated portion of spare resources, information associated with the repair request (e.g., information originally stored in the portion of the memory being repaired and/or similar information). The spare resources engine 308 may do so based on the information provided in the repair request received from resources tracker component 318 and thus without first requiring that the spare resources engine 308 map the logical addresses to sets of spare resources (e.g., without performing the operations described above in connection with reference number 224), without issuing a read operation to the spare resources in order to determine an occupation of the sets that are mapped to the logical addresses (e.g., without performing the operations described above in connection with reference number 226), and/or without choosing an available resource (e.g., way) of each set to be used for the repair operation (e.g., without performing some of the operations described above in connection with reference number 230). Additionally, or alternatively, there may be no need for the spare resources engine 308 to send a response to resources tracker component 318 indicating that a repair was successful and/or that enough repair resources were available for the repair operation (e.g., there may be no need for the spare resources engine to send a similar response to that described above in connection with reference number 232) because the resources tracker component 318 may keep track of the available resources and thus may be already have information stored in local memory that the repair resources indicated in the repair request are available (e.g., as indicated by reference number 312).

In this regard, if the central controller 304 receives a request (shown in FIG. 3B as a request 330) from a host device (e.g., via the frontend component 208) that is associated with Addr_1, the spare resources engine 308 may direct the request to the spare resources 310, and, more particularly, to Set A, Way 1 of the spare resources 310. Similarly, if the central controller 304 receives a request (e.g., request 330) from a host device (e.g., via the frontend component 208) that is associated with Addr_2, the spare resources engine 308 may direct the request to the spare resources 310, and, more particularly, to Set B, Way 3 of the spare resources 310.

As indicated above, FIGS. 3A-3B are provided as examples. Other examples may differ from what is described with regard to FIGS. 3A-3B.

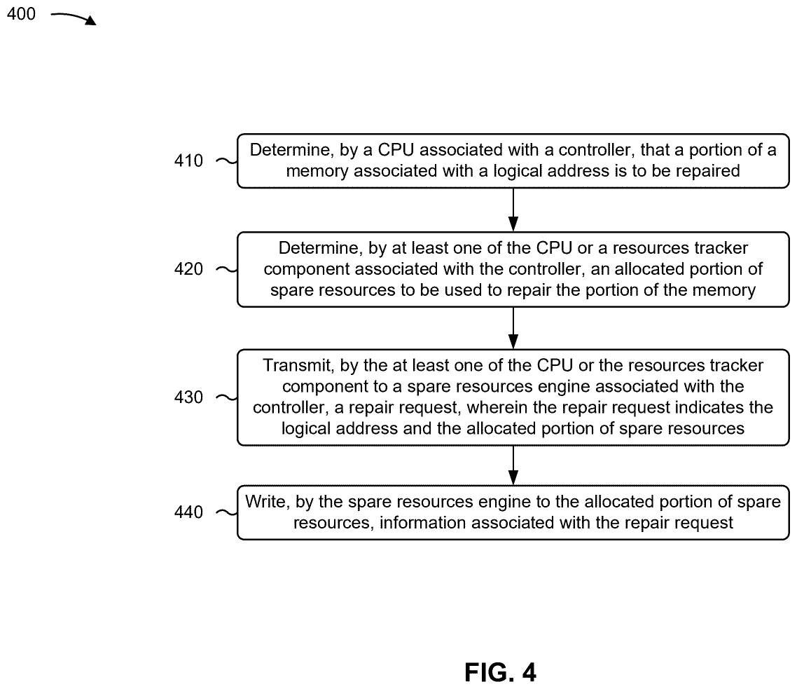

FIG. 4 is a flowchart of an example method 400 associated with allocation of repair resources in a memory device. In some implementations, a memory device (e.g., the memory device 120) and/or a memory system (e.g., the memory system 110) may perform or may be configured to perform the method 400. In some implementations, another device or a group of devices separate from or including the memory device (e.g., the system 100) may perform or may be configured to perform the method 400. Additionally, or alternatively, one or more components of the memory device and/or the memory system (e.g., the memory system controller 115, the local controller 125, the ASIC 202, the central controller 204, the spare resources engine 206, the CPU 214, the central controller 304, the CPU 306, the spare resources engine 308, and/or the resources tracker component 318) may perform or may be configured to perform the method 400. Thus, means for performing the method 400 may include the memory device, the memory system, and/or one or more components of the memory device and/or the memory system. Additionally, or alternatively, a non-transitory computer-readable medium may store one or more instructions that, when executed by the memory device and/or the memory system (e.g., the memory system controller 115 of the memory system 110), cause the memory device and/or the memory system to perform the method 400.

As shown in FIG. 4, the method 400 may include determining, by a CPU associated with a controller of a memory device, that a portion of a memory associated with a logical address is to be repaired (block 410). For example, the CPU 306 may determine that a portion of a memory (e.g., a portion of one or more memory arrays 130) associated with a logical address (e.g., Addr_1, Addr_2, or the like, as described above in connection with FIGS. 3A-3B) is to be repaired.

As further shown in FIG. 4, the method 400 may include determining, by at least one of the CPU or a resources tracker component associated with the controller, an allocated portion of spare resources to be used to repair the portion of the memory (block 420). For example, the CPU 306 and/or the resources tracker component 318 may determine an allocated portion of spare resources (e.g., Set A, Way 1; Set B, Way 3; or the like, as described above in connection with FIGS. 3A-3B) to be used to repair the portion of the memory.

As further shown in FIG. 4, the method 400 may include transmitting, by the at least one of the CPU or a resources tracker component to a spare resources engine associated with the controller, a repair request, wherein the repair request indicates the logical address and the allocated portion of spare resources (block 430). For example, the CPU 306 and/or the resources tracker component 318 may transmit, to the spare resources engine 308, a repair request (e.g., the repair request described above in connection with reference number 314 and/or the repair request described above in connection with reference number 324) that indicates the logical address (e.g., Addr_1 and/or Addr_2, among other examples) and the allocated portion of spare resources (e.g., Set A, Way 1; Set B, Way 3; or the like).

As further shown in FIG. 4, the method 400 may include writing, by the spare resources engine to the allocated portion of spare resources, information associated with the repair request (block 440). For example, the spare resources engine 308 may write, to the allocated portion of spare resources (e.g., spare resources 205, and, more particularly, Set A, Way 1; Set B, Way 3; or the like) information associated with the repair request (e.g., data previously stored at the physical memory locations associated with Addr_1 and/or Addr_2, among other examples).

The method 400 may include additional aspects, such as any single aspect or any combination of aspects described below and/or described in connection with one or more other methods or operations described elsewhere herein.

In a first aspect, determining the allocated portion of spare resources comprises determining the allocated portion of spare resources by the CPU (e.g., CPU 306).

In a second aspect, alone or in combination with the first aspect, determining the allocated portion of spare resources comprises determining the allocated portion of spare resources by the resources tracker component (e.g., resources tracker component 318).

In a third aspect, alone or in combination with one or more of the first and second aspects, the method 400 includes transmitting, by the CPU to the resources tracker component, another repair request, wherein the other repair request indicates the logical address, and determining, by the resources tracker component, the allocated portion of spare resources based on receiving the other repair request. For example, the CPU 306 may transmit, to the resources tracker component 318, another repair request (e.g., the repair request described above in connection with reference number 320) that indicates the logical address (e.g., Addr_1 and/or Addr_2, among other examples), and/or the resources tracker component 318 may determine the allocated portion of spare resources (e.g., Set A, Way 1; Set B, Way 3; or the like) based on receiving the other repair request.

In a fourth aspect, alone or in combination with one or more of the first through third aspects, the allocated portion of spare resources are associated with a SRAM located at the controller.

In a fifth aspect, alone or in combination with one or more of the first through fourth aspects, the spare resources include multiple sets of spare resources (e.g., Set A through Set C, among other examples), with each set of spare resources, of the multiple sets of spare resources, being associated with multiple ways (e.g., Way 0 through Way 3, among other examples), and wherein the repair request indicates at least one set of spare resources, of the multiple sets of spare resources, and at least one corresponding way, of the multiple ways (e.g., Set A, Way 1; Set B, Way 3; or the like), to be used to write the information associated with the repair request.

Although FIG. 4 shows example blocks of a method 400, in some implementations, the method 400 may include additional blocks, fewer blocks, different blocks, or differently arranged blocks than those depicted in FIG. 4. Additionally, or alternatively, two or more of the blocks of the method 400 may be performed in parallel. The method 400 is an example of one method that may be performed by one or more devices described herein. These one or more devices may perform or may be configured to perform one or more other methods based on operations described herein.

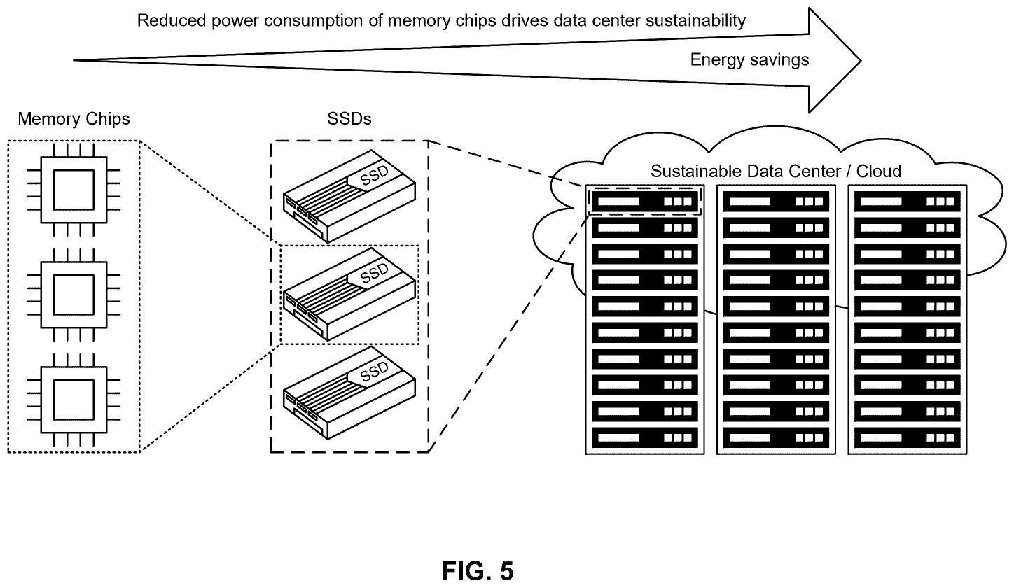

FIG. 5 is a diagram illustrating example systems in which the memory device 120 described herein may be used. In some implementations, one or more memory devices 120 may be included in a memory chip. Multiple memory chips may be packaged together and included in a higher level system, such as a solid state drive (SSD), a CXL memory device, or another type of memory drive and/or memory device. Each SSD and/or CXL memory device may include, for example, up to five memory chips, up to ten memory chips, or more. A data center or cloud computing environment may include multiple SSDs and/or CXL memory devices to store a large amount of data. For example, a data center may include hundreds, thousands, or more SSDs and/or CXL memory devices.

As described above, some implementations described herein reduce power consumption of a memory device 120. As shown in FIG. 5, this reduced power consumption drives data center sustainability and leads to energy savings because of the large volume of memory devices 120 included in a data center.

As indicated above, FIG. 5 is provided as an example. Other examples may differ from what is described with regard to FIG. 5.

In some implementations, a memory device includes one or more components configured to: determine, by a central processing unit (CPU) associated with a controller of the memory device, that a portion of a memory associated with a logical address is to be repaired; determine, by at least one of the CPU or a resources tracker component associated with the controller, an allocated portion of spare resources to be used to repair the portion of the memory; transmit, by the at least one of the CPU or the resources tracker component and to a spare resources engine associated with the controller, a repair request, wherein the repair request indicates the logical address and the allocated portion of spare resources; and write, by the spare resources engine to the allocated portion of spare resources, information associated with the repair request.

In some implementations, a method includes determining, by a central processing unit (CPU) associated with a controller of a memory device, that a portion of a memory associated with a logical address is to be repaired; determining, by at least one of the CPU or a resources tracker component associated with the controller, an allocated portion of spare resources to be used to repair the portion of the memory; transmitting, by the at least one of the CPU or the resources tracker component to a spare resources engine associated with the controller, a repair request, wherein the repair request indicates the logical address and the allocated portion of spare resources; and writing, by the spare resources engine to the allocated portion of spare resources, information associated with the repair request.

In some implementations, a memory controller is configured to: determine, by a central processing unit (CPU) of the memory controller, that a portion of a memory associated with a logical address is to be repaired; determine, by at least one of the CPU or a resources tracker component of the memory controller, an allocated portion of spare resources to be used to repair the portion of the memory; transmit, by the at least one of the CPU or the resources tracker component and to a spare resources engine of the memory controller, a repair request, wherein the repair request indicates the logical address and the allocated portion of spare resources; and write, by the spare resources engine to the allocated portion of spare resources, information associated with the repair request.

The foregoing disclosure provides illustration and description but is not intended to be exhaustive or to limit the implementations to the precise forms disclosed. Modifications and variations may be made in light of the above disclosure or may be acquired from practice of the implementations described herein.

As used herein, the terms “substantially” and “approximately” mean “within reasonable tolerances of manufacturing and measurement.”

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory device, comprising:
one or more components configured to:
determine, by a central processing unit (CPU) associated with a controller of the memory device, that a portion of a memory associated with a logical address is to be repaired;
determine, by at least one of the CPU or a resources tracker component associated with the controller, an allocated portion of spare resources to be used to repair the portion of the memory;
transmit, by the at least one of the CPU or the resources tracker component and to a spare resources engine associated with the controller, a repair request, wherein the repair request indicates the logical address and the allocated portion of spare resources; and
write, by the spare resources engine to the allocated portion of spare resources, information associated with the repair request.

2. The memory device of claim 1, wherein the one or more components, to determine the allocated portion of spare resources, are configured to determine the allocated portion of spare resources by the CPU.

3. The memory device of claim 1, wherein the one or more components, to determine the allocated portion of spare resources, are configured to determine the allocated portion of spare resources by the resources tracker component.

4. The memory device of claim 3, wherein the one or more components are further configured to:
transmit, by the CPU to the resources tracker component, another repair request, wherein the other repair request indicates the logical address; and
determine, by the resources tracker component, the allocated portion of spare resources based on receiving the other repair request.

5. The memory device of claim 1, wherein the allocated portion of spare resources are associated with a static random access memory (SRAM) located at the controller.

6. The memory device of claim 1, wherein the spare resources include multiple sets of spare resources, with each set of spare resources, of the multiple sets of spare resources, being associated with multiple ways, and
wherein the repair request indicates at least one set of spare resources, of the multiple sets of spare resources, and at least one corresponding way, of the multiple ways, to be used to write the information associated with the repair request.

7. The memory device of claim 1, wherein the at least one of the CPU or the resources tracker component, the spare resources engine, and the spare resources are part of an application-specific integrated circuit associated with the controller.

8. A method, comprising:
determining, by a central processing unit (CPU) associated with a controller of a memory device, that a portion of a memory associated with a logical address is to be repaired;
determining, by at least one of the CPU or a resources tracker component associated with the controller, an allocated portion of spare resources to be used to repair the portion of the memory;
transmitting, by the at least one of the CPU or the resources tracker component to a spare resources engine associated with the controller, a repair request, wherein the repair request indicates the logical address and the allocated portion of spare resources; and
writing, by the spare resources engine to the allocated portion of spare resources, information associated with the repair request.

9. The method of claim 8, wherein determining the allocated portion of spare resources comprises determining the allocated portion of spare resources by the CPU.

10. The method of claim 8, wherein determining the allocated portion of spare resources comprises determining the allocated portion of spare resources by the resources tracker component.

11. The method of claim 10, further comprising:
transmitting, by the CPU to the resources tracker component, another repair request, wherein the other repair request indicates the logical address; and
determining, by the resources tracker component, the allocated portion of spare resources based on receiving the other repair request.

12. The method of claim 8, wherein the allocated portion of spare resources are associated with a static random access memory (SRAM) located at the controller.

13. The method of claim 8, wherein the spare resources include multiple sets of spare resources, with each set of spare resources, of the multiple sets of spare resources, being associated with multiple ways, and
wherein the repair request indicates at least one set of spare resources, of the multiple sets of spare resources, and at least one corresponding way, of the multiple ways, to be used to write the information associated with the repair request.

14. A memory controller, configured to:
determine, by a central processing unit (CPU) of the memory controller, that a portion of a memory associated with a logical address is to be repaired;
determine, by at least one of the CPU or a resources tracker component of the memory controller, an allocated portion of spare resources to be used to repair the portion of the memory;
transmit, by the at least one of the CPU or the resources tracker component and to a spare resources engine of the memory controller, a repair request, wherein the repair request indicates the logical address and the allocated portion of spare resources; and
write, by the spare resources engine to the allocated portion of spare resources, information associated with the repair request.

15. The memory controller of claim 14, wherein the memory controller, to determine the allocated portion of spare resources, is configured to determine the allocated portion of spare resources using the CPU.

16. The memory controller of claim 14, wherein the memory controller, to determine the allocated portion of spare resources, is configured to determine the allocated portion of spare resources using the resources tracker component.

17. The memory controller of claim 16, wherein the memory controller is further configured to:
transmit, by the CPU to the resources tracker component, another repair request, wherein the other repair request indicates the logical address; and
determine, by the resources tracker component, the allocated portion of spare resources based on receiving the other repair request.

18. The memory controller of claim 14, wherein the allocated portion of spare resources are associated with a static random access memory (SRAM) of the memory controller.

19. The memory controller of claim 14, wherein the spare resources include multiple sets of spare resources, with each set of spare resources, of the multiple sets of spare resources, being associated with multiple ways, and
wherein the repair request indicates at least one set of spare resources, of the multiple sets of spare resources, and at least one corresponding way, of the multiple ways, to be used to write the information associated with the repair request.

20. The memory controller of claim 14, wherein the at least one of the CPU or the resources tracker component, the spare resources engine, and the spare resources are part of an application-specific integrated circuit associated with the memory controller.
